(19) United States
(12) Patent Application Publication
(10) Pub. No.: US 2017/0257095 A1
(43) Pub. Date: Sep. 7, 2017

(54) ACTUATION PLATE WITH SYMBOL ILLUMINATION FOR A SENSOR SWITCH BUTTON

(71) Applicant: Delphi Technologies, Inc., Troy, MI (US)

(72) Inventor: Erik Reischl, Birkenfeld (DE)

(21) Appl. No.: 15/433,465

(22) Filed: Feb. 15, 2017

(30) Foreign Application Priority Data
Mar. 1, 2016 (EP) 16157992.5

(51) Int. Cl. H03K 17/96; F21V 8/00

(52) U.S. Cl. CPC H03K 17/962; G02B 6/0051; G02B 6/0008

(57) ABSTRACT

An actuation plate with symbol illumination for a sensor switch button includes a support plate with a first surface on which a metal layer is applied. A luminous layer of light-scattering material is applied on the support plate and at least partially on the metal layer. An opening is provided in the support plate through which a first end of a light guide projects, and a second end of the light guide is optically connected to a light source. The luminous layer is adjacent to the first end of the light guide.

### CROSS-REFERENCE TO RELATED APPLICATION

This application claims the benefit under 35 U.S.C. §119(a) of European Patent Application EP 16157992.5, filed Mar. 1, 2016, the entire disclosure of which is hereby incorporated herein by reference.

### TECHNICAL FIELD OF INVENTION

This disclosure generally relates to an actuation plate with symbol illumination for a sensor switch button for use in a switch arrangement of a vehicle.

### BACKGROUND OF INVENTION

For several years, switches that are operated by tapping with a finger have been used in vehicles. These switches are very advantageous since they do not require mechanical components and are therefore very robust. These switches have been used in vehicles for switching various functions. Unfortunately, children who unintentionally actuate such a switch with a body part such as a knee or foot whilst playing unattended in the interior of a vehicle may be injured. If, for example, an electric sliding roof is actuated by the child with the foot, while at the same time a body part is located in the opening of the sliding roof, serious injuries may occur. This circumstance makes it necessary to develop sensors which detect how large the contact area of the object is. A capacitance sensor which is suitable for distinguishing the size of a fingertip from larger body parts, such as, for example, a ball of the hand, can be produced relatively inexpensively. Such a sensor can be produced by dividing the copper coating of a commercially available printed circuit board (PCB) into adequate surface areas and separating the areas by narrow gaps. These separate areas are electrically connected to an electronic evaluation unit. These areas now represent capacitor plates. The capacitance of the capacitor changes if a user finger interacts with it. Depending on the size and distribution of the surface areas as well as the programming of the electronic evaluation unit, bodies of different sizes and even their direction of movement can be recognized. If there is only a small distance between the sensor surfaces and the operator finger (lacquer layer), the sensitivity of the sensor is even increased. If such a sensor is used in a switch arrangement, in particular in a vehicle, it is desirable to design the switch illuminable. The method widely used in the art for illuminating switch heads from the inside does not work here. The printed circuit board and in particular the copper coating are optically opaque. One common method of solving this problem is the use of an acrylic glass pane, which is arranged in front of the sensor surface and into which light is coupled laterally. A symbol applied to the pane is thereby made visible in the dark. For this arrangement to function in an acceptable manner, the acrylic glass pane needs to have a minimum thickness. The greater distance resulting between the sensor surface and the user finger results in poorer detection accuracy. In addition, the acrylic glass pane and the light source, which is usually arranged laterally on the acrylic glass pane, need space so that a corresponding switch head may need to have a minimum size. This circumstance limits the design options in the vehicle.

### SUMMARY OF THE INVENTION

The object of the invention is to provide an actuation plate for a sensor switch button with high detection sensitivity and resolution which has an illumination capability.

The object is achieved by an actuation plate with symbol illumination for a sensor switch button, comprising a support plate with a first surface on which a metal layer is applied. A luminous layer of light-scattering material is applied on the support plate and at least partially on the metal layer. An opening is provided in the support plate through which a first end of a light guide projects, a second end of the light guide is optically connected to a light source, wherein the luminous layer is adjacent to the first end of the light guide.

The actuation plate according to the invention, taken by itself, is a module which can be used for capacitive detection by an associated control unit, for example, in the manner initially described. The metal layer applied to the support plate serves as sensor electrode. To obtain a high detection sensitivity and resolution of the actuation plate, the metal layer is applied over the entire surface of the support plate. To protect the metal layer and for aesthetic reasons, the actuator plate is provided with a plastic coating. Lacquer coatings may also be used to keep the layer thickness even smaller. The area which is provided for the luminous layer is not coated. Here, a luminous layer of light-scattering material is applied. Light-scattering materials are known in lighting technology. The luminous layer may, for example, have a pane-shaped design or may have any desired shape. The actuation plate has an opening through which an end of a light guide projects, the luminous layer is arranged on the support plate such that light from the light guide may be coupled into the luminous layer. Coupled means that light from the light guide may be emitted into the luminous layer. The light is then diffusely distributed in the luminous layer and perceived as a luminous surface by the operator. The second end of the light guide is connected to a light source which couples the light into the light guide. Nowadays, light-emitting diodes are mainly used as light sources due to their small overall size. Advantageously, the light source can be arranged on the second side of the support plate, which results in a particularly compact structure. However, in principle all types of light sources can be used. To obtain a particularly advantageous lighting result, the second end of the light guide is arranged in the edge region of the luminous layer. This prevents light spots in the middle of the luminous layer, which are unaesthetic in appearance.

Advantageous embodiments of the invention are provided in the dependent claims, the description, and the figures.

According to an embodiment, the opening extends through the metal layer. Depending on the distribution of the metal surfaces on the support plate and the desired position of the luminous layer, it may be necessary to provide the opening also through the metal surface. Since the opening is small relative to the area of the metal surface, the sensor performance is not significantly influenced.

Preferably, the luminous layer has a layer thickness of 1 to 2 mm. The luminous layer needs to have a certain layer thickness to ensure an acceptable light distribution in the diffuse material.

According to a further embodiment, the luminous layer has a circular circumference, wherein the layer thickness of the luminous layer is one tenth of the diameter of the luminous layer. If the luminous layer is provided with circular or elliptical circumference, it can be assumed that the structure according to the proposed ratio produces a good lighting result.

Preferably, the support plate is without openings in the area in which the luminous layer is adjacent to the metal layer and/or the support plate. The actuation plate needs to be functional also in the area of the luminous layer so that persons can reliably actuate a switch in the dark. Without opening in this area, a maximum sensor area is possible.

According to a further embodiment, the light source is attached to the second surface, so that the emitted light emits directly into the opening. When using a (reverse gullwing) LED, it illuminates the printed circuit board on which it is attached. If the LED is positioned above the opening, it emits through the opening. Since a light guide is located in the opening, the light is guided, which improves the efficiency. The opening extends essentially perpendicular to the support plate. Perpendicular bores are the easiest to produce in production. However, obliquely bores could also be provided, if required, wherein the coupling surface should remain parallel to the light source.

Preferably, the luminous layer is arranged spaced apart from the edge of the support plate. In general, symbol illuminations are arranged centrally on a switch to quickly guide the operator to the actuation point in the dark.

According to a further embodiment, the luminous layer spreads conically or curved from the support plate. In this embodiment, the luminous layer has a smaller surface facing the support plate and a larger surface facing the user. This structure has the advantage that, when the luminous layer is provided as an insert, this part can be easily positioned and fixed in a respective bowl-shaped reception in the plastic coating during mounting of the actuation plate. Furthermore, the end of the light guide can be adapted more to the oblique edge area.

Preferably, the first end of the light guide has a decoupling surface that is complementary to the side wall of the luminous layer. Here, the term complementary is to be understood as meaning that the surfaces are provided such that, when connected, they have a connection area as large as possible, wherein the separating air gap should be as small as possible. Some examples:

The edge area of the luminous layer has a planar surface and the first end of the light guide also has a planar surface, the two planar surfaces having substantially the same size. The edge area of the luminous layer has a curved part (in the case of a cylindrical luminous layer) and the first end of the light guide has a recess which adjoins the curved part. The edge area of the luminous layer has a recess (in the case of a cylindrical luminous layer) and the first end of the light guide has a curved part which adjoins the recess. The luminous layer extends at an angle of 45 degrees from the support plate plane to the edge and the first end of the light guide is at an angle of 45 degrees. This structure makes it possible to position the first end of the light guide at the edge of the luminous layer such that the maximum coupling area is achieved when the surfaces are complementary.

Advantageously, the light guide has a plurality of first ends, which are arranged along the circumference of the luminous layer. To achieve a homogeneous illumination of the luminous layer, it is advantageous to provide a plurality of coupling locations. If a number of locations along the circumference of the luminous layer are supplied with light, an appealing symbol illumination is achieved.

Preferably, the luminous layer contains a luminescent material which is suitable to produce white light from higher-energy light. In some applications, it may be easier to transport UV light or blue light through the light guide and then convert the light into white light in the luminous layer. The diffuse material or diffuser material would then have to be provided with corresponding components which are known in the art.

Preferably, the support plate is a printed circuit board having a plurality of closely spaced conductor surfaces largely covering the first surface, forming the sensor surface of a capacitive sensor. A low-cost actuation plate can be produced if a commercially available printed circuit board with copper lamination is used as the support plate. The capacitor plates of the sensor are formed by the copper surfaces. Depending on the requirements, different layouts can be created for the distribution of the conductor surfaces.

Preferably, the cross-sectional area of the opening is substantially smaller than a surface area of the conductive surfaces of the capacitive sensor. The sensor surface should be as homogeneous as possible so that the actuation plate functions as best as possible. If openings for the symbol illumination are to be provided, they should be as small as possible. The openings should not exceed a diameter of 1.5 mm. For non-circular openings, the surface area of the opening should be below 2 mm².

Advantageously, the actuation plate is arranged movably and the light guide is formed of at least one polymer optical fiber. The actuation plate may be integrated into a switch which provides a mechanical switching function. To suggest to the user the haptic feeling to actuate a switch, the switch needs to be moveable. Depending on the space conditions, it may be necessary to position the light source for symbol illumination remote or stationary. By means of a polymer optical fiber, the movable actuation plate can nevertheless be supplied with light. The required flexibility is provided by the polymer optical fiber.

The luminous layer and the cap can be provided with a decorative layer by means of a symbolizing method. These methods use a lacquer layer in which symbols are imprinted by laser.

The invention further relates to a sensor switch button comprising an actuation plate.

In accordance with one embodiment, an actuation plate with symbol illumination for a sensor switch button is provided. The plate includes a support plate with a first surface on which a metal layer is applied. A luminous layer of light-scattering material is applied on the support plate and at least partially on the metal layer. An opening is defined in the support plate through which a first end of a light guide projects. A second end of the light guide is optically connected to a light source, and the luminous layer is adjacent to the first end of the light guide.

Further features and advantages will appear more clearly on a reading of the following detailed description of the preferred embodiment, which is given by way of non-limiting example only and with reference to the accompanying drawings.

### BRIEF DESCRIPTION OF DRAWINGS

In the following, the invention is described by means of an advantageous embodiment only by way of example with reference to the attached figures in which:

FIG. 1 shows a sensor switch button with integrated actuation plate and symbol illumination in a sectional view;

FIG. 2 shows a top view of an actuation plate;

FIG. 3 shows the structure of an actuation plate with symbol illumination in a sectional view;

FIG. 4 shows an alternative structure of a sensor switch button with actuation plate and symbol illumination;

FIG. 5 shows a top view of an actuation plate; and

FIG. 6 shows the first end of a light guide and the adjacent area of the luminous layer.

### DETAILED DESCRIPTION

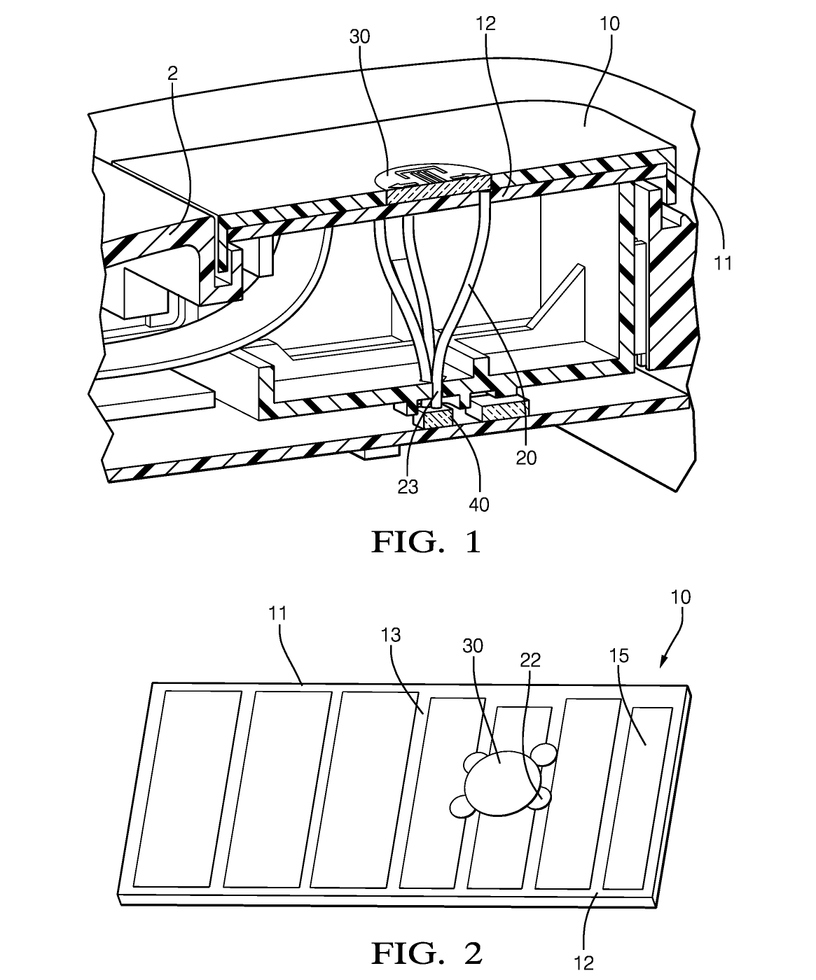

FIG. 1 shows a sensor switch button 1 with integrated actuation plate 10 and symbol illumination. The first surface 13 of the actuation plate 10 is covered by a cap 17. The cap 17 serves to protect the sensor surface and to hold the actuation plate 10 on the housing 2 of the switch. The cap 17 has a recess in the middle area of the surface into which a luminous layer 30 is embedded. Light guides 20 extend in the direction of the actuation plate 10 from a light source 40 which is attached to a second printed circuit board. The light guides 20 reach the actuation plate 10 at the second surface 13b. In this embodiment, the actuation plate 10 is movably connected to the housing 2. Here, the light guides 20 are formed of flexible polymer optical fibers.

FIG. 2 shows a top view of the first surface 13 of the actuation plate 10. A plurality of metal layers 15 are applied to a support plate 12, which are separated by narrow areas from one another. Here, the metal layers 15 are shown as a series of strips. These conductor surfaces 16 form the sensor elements of a capacitance sensor. A luminous layer 30 is shown centrally on the first surface 13 and spaced apart from the edge 11 of the support plate 12. A plurality of first ends 22 of a light guide 20 are shown at the edge of the luminous layer 30. The first ends 22 are distributed uniformly along the circumference of the luminous layer 30.

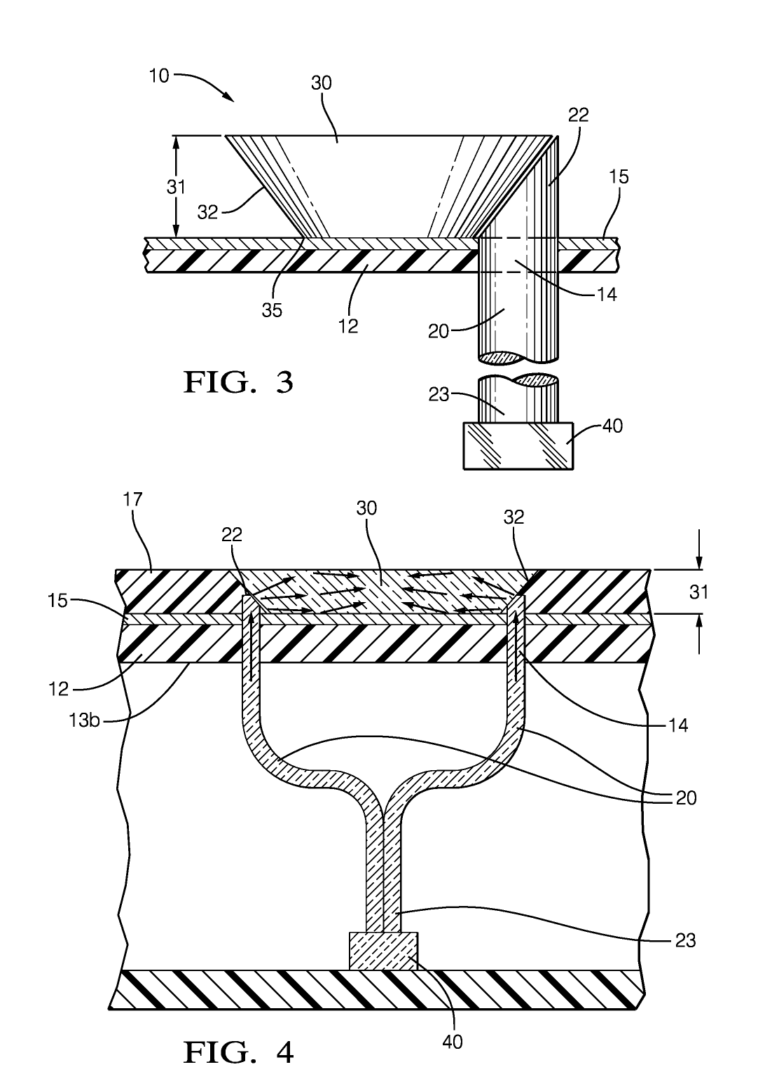

FIG. 3 shows the basic structure of an actuation plate 10 with symbol illumination in a sectional view. A luminous layer 30 is attached to the first surface 13 of a support plate 12. Preferably, the luminous layer 30 is located on the support plate 12 and/or on the metal layer. An edge area 35 extends along the circumference of the luminous layer 30, which is adjacent to the support plate 12. Adjacent to the edge area 35 of the luminous layer 30, an opening 14 is provided in the support plate 12 through which the first end 22 of a light guide 20 projects. The first end 22 of the light guide 20 and the side wall 32 of the luminous layer 30 are formed such that the first end 22 of the light guide 20 adjoins the side wall 32. The second end 23 of the light guide 20 is optically connected to a light source 40.

FIG. 4 shows an alternative structure of a sensor switch button 1 with actuation plate 10 and symbol illumination in a sectional view. To improve the lighting of the symbol illumination, a structure with two first ends 22 of the light guide 20 is shown herein. The first ends 22 of the light guide 20 are attached to opposite side walls of the luminous layer 30. The light guides are combined to the light guide 20 and form a single second light guide end 23. The second light guide end is optically connected to a light source 40. A cap 17, surrounding the luminous layer 30, is provided on the first surface 13 in the area outside the luminous layer 30 for protection of the first surface. The layer thickness of the cap 17 is matched to the layer thickness 31 of the luminous layer 30.

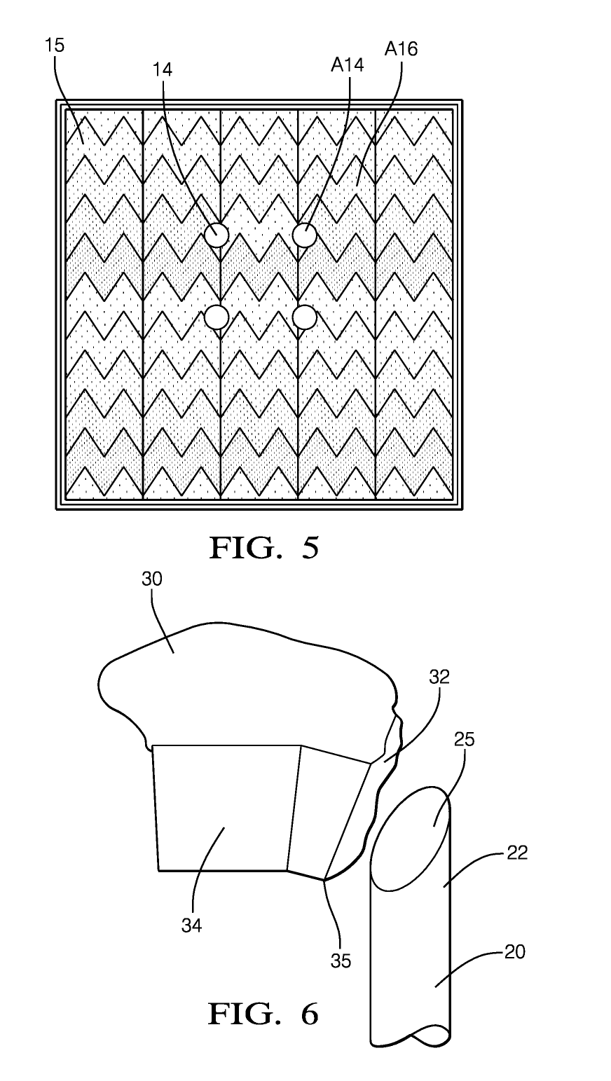

FIG. 5 shows a top view of an actuation plate 10. In this top view of the first surface 13 of the actuation plate 10, the openings 14 are shown without the first ends 22 of the light guide 20. The conductor surfaces 16 cover almost the entirety of the first surface 13 of the support plate 12. The openings 14 extend through the support plate 12 and additionally, in areas, through the conductor surfaces 16. The conductor surfaces 16 occupy much larger areas than the openings 14.

FIG. 6 shows the first end 22 of a light guide 20 and the adjacent area of the luminous layer 30. The first end 22 of the light guide 20 is prepared such as to correspond to the side wall 32 of the luminous layer 30. This means that the largest possible amount of light is transmitted from the decoupling surface 25 of the first end 22 of the light guide 20 to the coupling surface 34 of the luminous layer 30. Here, the first light guide end 22 is provided with a flat surface at an angle. The side wall 32 of the luminous layer 30 is also provided with a flat surface at a corresponding position, which is arranged at a corresponding angle. If these two surfaces are arranged adjacent to each other, the largest amount of light is transmitted.

While this invention has been described in terms of the preferred embodiments thereof, it is not intended to be so limited, but rather only to the extent set forth in the claims that follow.

We claim:

1. An actuation plate with symbol illumination for a sensor switch button, said plate comprising: a support plate with a first surface on which a metal layer is applied, wherein a luminous layer of light-scattering material is applied on the support plate and at least partially on the metal layer, and wherein an opening is defined in the support plate through which a first end of a light guide projects, a second end of the light guide is optically connected to a light source, and the luminous layer is adjacent to the first end of the light guide.

2. The actuation plate according to claim 1, wherein the opening extends through the metal layer.

3. The actuation plate according to one of the preceding claims, characterized in that the luminous layer has a layer thickness of 1 mm to 2 mm.

4. The actuation plate according to claim 1, wherein the luminous layer has a circular circumference, wherein the layer thickness of the luminous layer is one tenth of the diameter of the luminous layer.

5. The actuation plate according to claim 1, wherein the support plate is without openings in the area in which the luminous layer is adjacent to the metal layer and the support plate.

6. The actuation plate according to claim 1, wherein the light source is attached to the second surface so that the emitted light emits directly into the opening.

7. The actuation plate according to claim 1, wherein the luminous layer is spaced apart from the edge of the support plate.

8. The actuation plate according to claim 1, wherein the luminous layer spreads conically or curved from the support plate.

9. The actuation plate according to claim 1, wherein the first end of the light guide has a decoupling surface that is formed complementary to the side wall of the luminous layer.

10. The actuation plate according to claim 1, wherein the light guide has a plurality of first ends which are arranged along the circumference of the luminous layer.

11. The actuation plate according to claim 1, wherein the luminous layer contains luminescent material which is suitable to produce white light from higher-energy light.

12. The actuation plate according to claim 1, wherein the support plate is a printed circuit board and forming the sensor surface of a capacitive sensor with a plurality of closely spaced conductor surfaces largely covering the first surface.

13. The actuation plate according to claim 12, characterized in that a cross-sectional area of the opening is substantially smaller than a surface area of the conductor surfaces of the capacitive sensor.

14. The actuation plate according to claim 1, wherein the actuation plate is movably arranged and the light guide is formed of at least one polymer optical fiber.

15. A sensor switch button comprising an actuation plate according to claim 1.
